(19) United States
(12) Patent Application Publication
(10) Pub. No.: US 2026/0239636 A1
(43) Pub. Date: Aug. 13, 2026

(54) METHOD FOR FORMING SEMICONDUCTOR STRUCTURE AND SEMICONDUCTOR STRUCTURE

(71) Applicant: CXMT Corporation, Hefei, Anhui (CN)

(72) Inventors: Hang Yu, Hefei (CN); Mingxu Liu, Hefei (CN); Min-Hui Chang, Hefei (CN); Jie Li, Hefei (CN); Hui Li, Hefei (CN); Zhenchu Zhou, Hefei (CN)

(73) Assignee: CXMT Corporation, Hefei, Anhui (CN)

(21) Appl. No.: 19/425,085

(22) Filed: Dec. 18, 2025

Related U.S. Application Data
(63) Continuation of application No. PCT/CN2025/135436, filed on Nov. 17, 2025.

(30) Foreign Application Priority Data
Feb. 12, 2025 (CN) 202510153812.8

(51) Int. Cl. H10D 1/68; H10B 12/00; H10D 1/00

(52) U.S. Cl. CPC H10D 1/696; H10B 12/318; H10D 1/041; H10D 1/716

(57) ABSTRACT

The present disclosure a method for manufacturing a semiconductor structure. The method includes: providing a base substrate, and forming a stack structure on the base substrate; etching the stack structure to form a first capacitor hole; forming a first initial electrode layer, a second electrode layer, and a third electrode layer sequentially in the first capacitor hole, where an oxidation resistance of the second electrode layer is greater than oxidation resistances of the first initial electrode layer and the third electrode layer; removing a part of the stack structure and a part of the first initial electrode layer to form a second capacitor hole, with a remaining part of the first initial electrode layer serving as a first electrode layer; and forming a dielectric layer and an upper electrode in the second capacitor hole.

### CROSS-REFERENCE

This application is a continuation of International Patent Application No. PCT/CN2025/135436, filed on Nov. 17, 2025, which claims the benefit of Chinese Patent Application No. 202510153812.8, titled "METHOD FOR FORMING SEMICONDUCTOR STRUCTURE AND SEMICONDUCTOR STRUCTURE", filed with the China National Intellectual Property Administration (CNIPA) on February 12, 2025, the disclosures of which are incorporated herein by reference in their entireties.

### TECHNICAL FIELD

Embodiments of the present disclosure relate to the field of semiconductors, and in particular, to a method for forming a semiconductor structure and a semiconductor structure.

### BACKGROUND

With the advancement of DRAM technology nodes, the dimension of chips continues to shrink, and the radius of capacitors needs to be gradually reduced. However, how to reduce the radius of the capacitors and how to solve the phenomenon of capacitor bending and toppling that occurs during the process of reducing the radius of the capacitors are urgent technical problems to be solved in the field of semiconductors.

### SUMMARY

Embodiments of the present disclosure provide a method for forming a semiconductor structure and a semiconductor structure, which are at least conducive to solving the problem of capacitor bending and toppling that occurs during the process of reducing the radius of the capacitor.

According to some embodiments of the present disclosure, an aspect of the embodiments of the present disclosure provides a method for manufacturing a semiconductor structure. The method includes:

providing a base substrate, and forming a stack structure on the base substrate;

etching the stack structure to form a first capacitor hole;

forming a first initial electrode layer, a second electrode layer, and a third electrode layer sequentially in the first capacitor hole, where an oxidation resistance of the second electrode layer is greater than oxidation resistances of the first initial electrode layer and the third electrode layer;

removing a part of the stack structure and a part of the first initial electrode layer to form a second capacitor hole, with a remaining part of the first initial electrode layer serving as a first electrode layer, where the first electrode layer, the second electrode layer, and the third electrode layer form a lower electrode; and

forming a dielectric layer and an upper electrode in the second capacitor hole, where the dielectric layer covers the lower electrode, and the second capacitor hole is filled with the upper electrode.

Another aspect of the embodiments of the present disclosure provides a semiconductor structure. The semiconductor structure includes:

a base substrate, where a stack structure is provided on the base substrate, and the stack structure is provided with a first capacitor hole;

a lower electrode, located in the first capacitor hole, where the lower electrode at least includes a first electrode layer, a second electrode layer, and a third electrode layer, an oxidation resistance of the second electrode layer being greater than oxidation resistances of the first electrode layer and the third electrode layer;

a second capacitor hole, formed by removing at least a part of the stack structure; and

a dielectric layer and an upper electrode, located in the second capacitor hole, where the dielectric layer covers the lower electrode, and the second capacitor hole is filled with the upper electrode.

### BRIEF DESCRIPTION OF DRAWINGS

One or more embodiments are exemplarily illustrated by figures in corresponding drawings, and the exemplary illustration is not to be construed as limiting the embodiments. Unless otherwise specified, the figures in the drawings do not constitute limitations in terms of scale. To more clearly illustrate the technical solutions in the embodiments of the present disclosure or in conventional techniques, the drawings required to be used in the embodiments are briefly described below. It is clear that the drawings in the description below are only some embodiments of the present disclosure, and for those of ordinary skill in the art, other drawings may also be obtained based on these drawings without creative efforts.

FIG. 1 is a flow block diagram of a method for manufacturing a semiconductor structure;

FIGS. 2A to 2M are process flowcharts showing a method for manufacturing a semiconductor structure according to an embodiment of the present disclosure, where FIG. 2A is a schematic diagram showing the formation of a stack structure, FIG. 2B is a schematic diagram showing the formation of a first capacitor hole, FIG. 2C is a schematic diagram showing the formation of a first initial electrode layer, FIG. 2D is a schematic diagram showing the formation of a second electrode layer, FIG. 2E is a schematic diagram showing the formation of a third electrode layer, FIG. 2F is a schematic diagram showing the removal of a first initial electrode layer, a second electrode layer, and a third electrode layer that are above a top supporting layer, FIG. 2G is a schematic diagram showing the formation of an initial top opening, FIG. 2H is a schematic diagram showing the formation of a top opening and a first sacrificial opening, FIG. 2I is a schematic diagram showing the formation of an intermediate opening, FIG. 2J is a schematic diagram showing the formation of a second capacitor hole, FIG. 2K is a schematic diagram showing the formation of a dielectric layer, FIG. 2L is a schematic diagram showing the formation of a first upper electrode layer, and FIG. 2M is a schematic diagram showing the formation of a second upper electrode layer;

FIG. 3 is a schematic diagram of a semiconductor structure according to an embodiment of the present disclosure;

FIG. 4 is an enlarged schematic diagram of portion A in FIG. 3;

FIG. 5 is an enlarged schematic diagram of portion B in FIG. 3; and

FIG. 6 is an enlarged schematic diagram of portion C in FIG. 3.

### DESCRIPTION OF EMBODIMENTS

As is known from the background, with the advancement of the DRAM technology nodes, the dimension of chips continues to shrink, and the radius of capacitors needs to be gradually reduced. However, how to reduce the radius of the capacitors and how to solve the phenomenon of capacitor bending and toppling that occurs during the process of reducing the radius of the capacitors are urgent technical problems to be solved in the field of semiconductors.

The embodiments of the present disclosure provide a method for forming a semiconductor structure and a semiconductor structure. By sequentially forming a first initial electrode layer, a second electrode layer, and a third electrode layer in a first capacitor hole, a part of the first initial electrode layer is removed to form a first electrode layer, and the oxidation resistance of the second electrode layer is greater than the oxidation resistances of the first electrode layer and the third electrode layer. Since a part of the first initial electrode layer is removed to form the first electrode layer, the radius of a lower electrode of the capacitor is reduced. In addition, the oxidation resistance of the second electrode layer is greater than the oxidation resistances of the first electrode layer and the third electrode layer, such that deformation and bending caused by the oxidation of the lower electrode are prevented during subsequent deposition of a dielectric layer, thereby improving the performance of the semiconductor structure.

The embodiments of the present disclosure will be described in detail below with reference to the drawings. However, those of ordinary skill in the art can understand that in the embodiments of the present disclosure, numerous technical details are set forth to enable readers to better understand the present disclosure. However, the technical solutions claimed by the present disclosure can also be implemented even without these technical details and the various changes and modifications based on the following embodiments.

The present disclosure is more specifically described in the following paragraphs with reference to the drawings by way of example. Advantages and features of the present disclosure will become apparent from the following description and claims. It should be noted that the drawings are all in a very simplified form and not to a precise scale, and are provided only for the purpose of facilitating a convenient and clear description of the embodiments of the present disclosure.

It can be understood that the meaning of “on”, “above”, and “over” in the present disclosure should be interpreted in the broadest manner, such that “on” not only includes the meaning of “on” something with no intermediate feature or layer therebetween (i.e., directly on something) but also includes the meaning of “on” something with an intermediate feature or a layer therebetween.

In the embodiments of the present disclosure, the terms “first”, “second”, “third”, and the like are used for distinguishing similar objects and are not necessarily used for describing a particular order or sequence.

In the embodiments of the present disclosure, the term “layer” refers to a material portion that includes a region having a thickness. A layer may extend over the entirety of the underlying or overlying structure or may have an extent that is less than the extent of the underlying or overlying structure. Furthermore, a layer may be a region of a homogeneous or inhomogeneous continuous structure having a thickness less than the thickness of a continuous structure. For example, a layer may be located between the top surface and the bottom surface of a continuous structure, or a layer may be located between any pair of horizontal planes at the top surface and the bottom surface of the continuous structure. A layer may extend horizontally, perpendicularly, and/or along inclined surfaces. A layer may include a plurality of sub-layers.

It should be noted that the technical solutions described in the embodiments of the present disclosure may be combined arbitrarily without conflict.

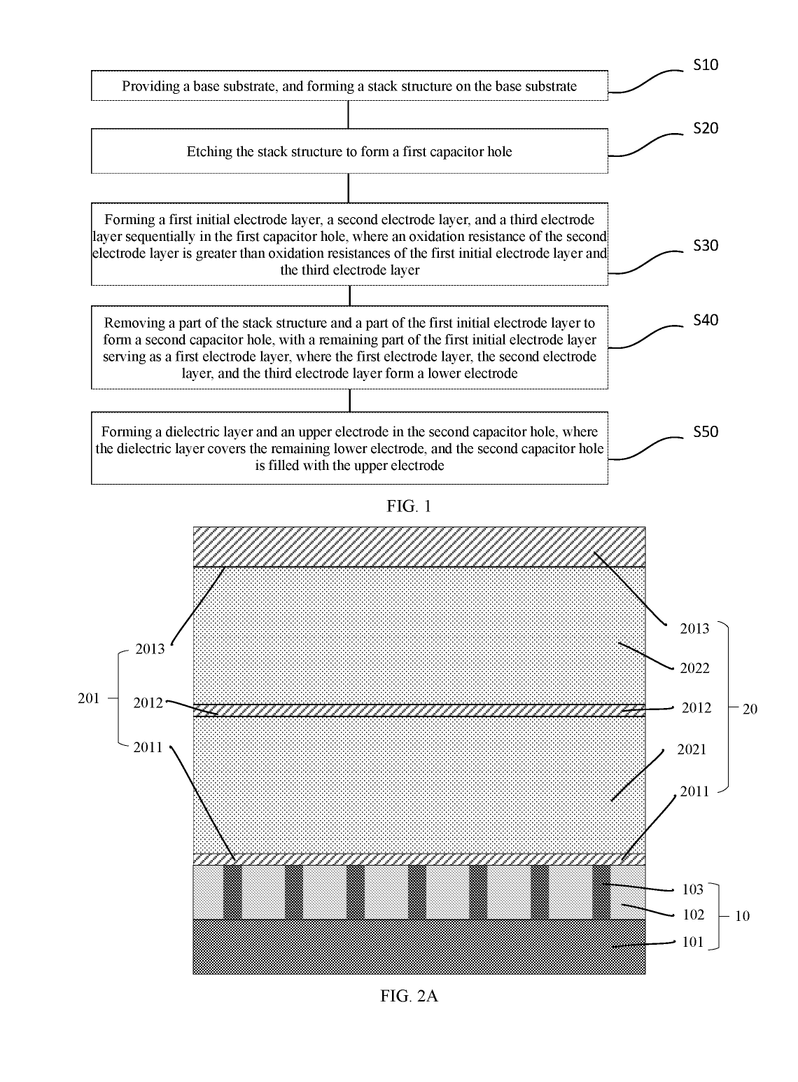

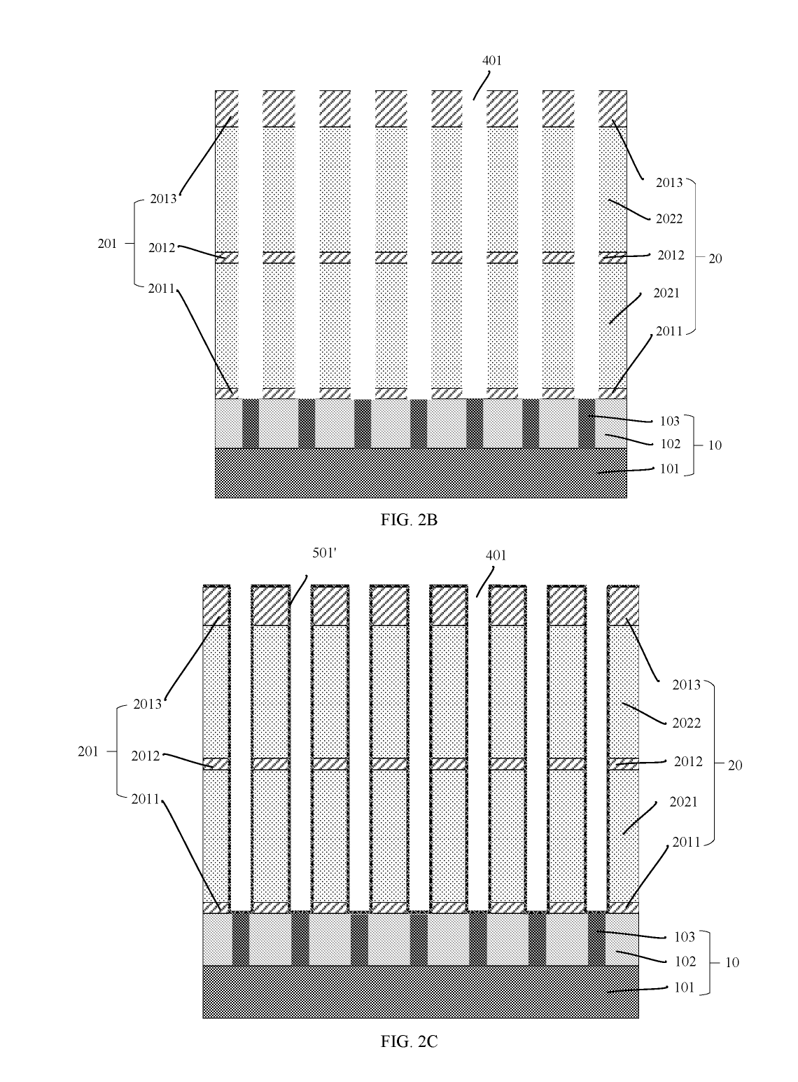

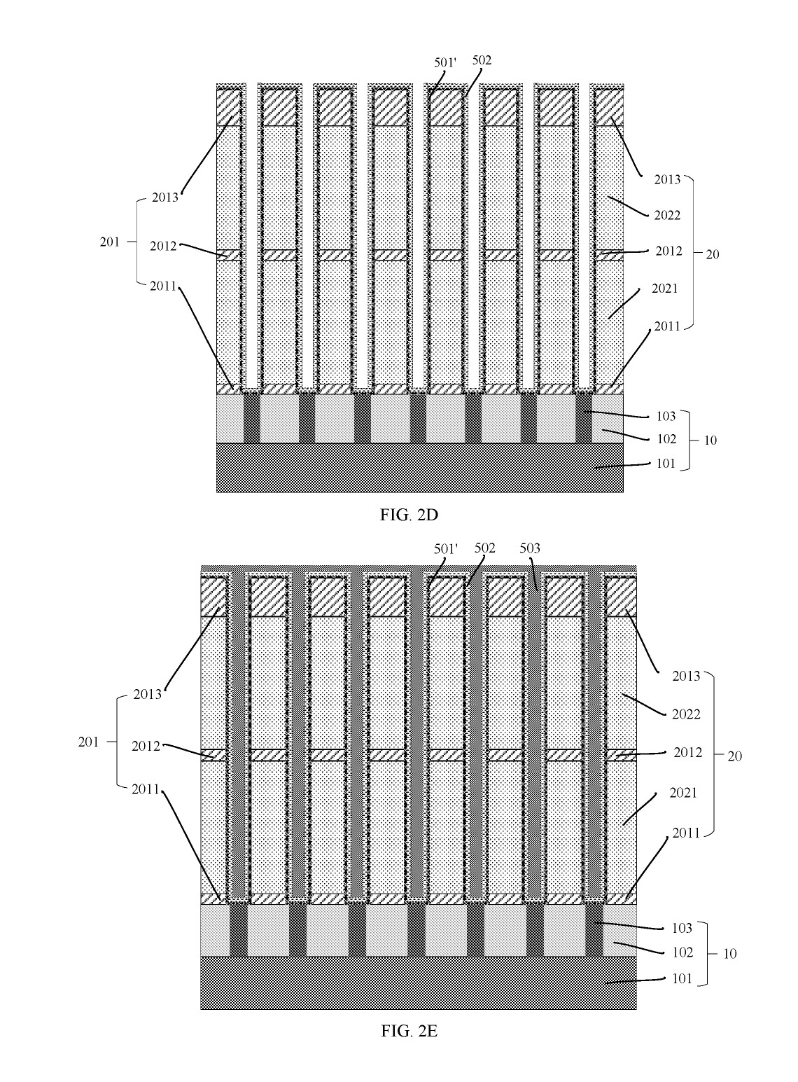

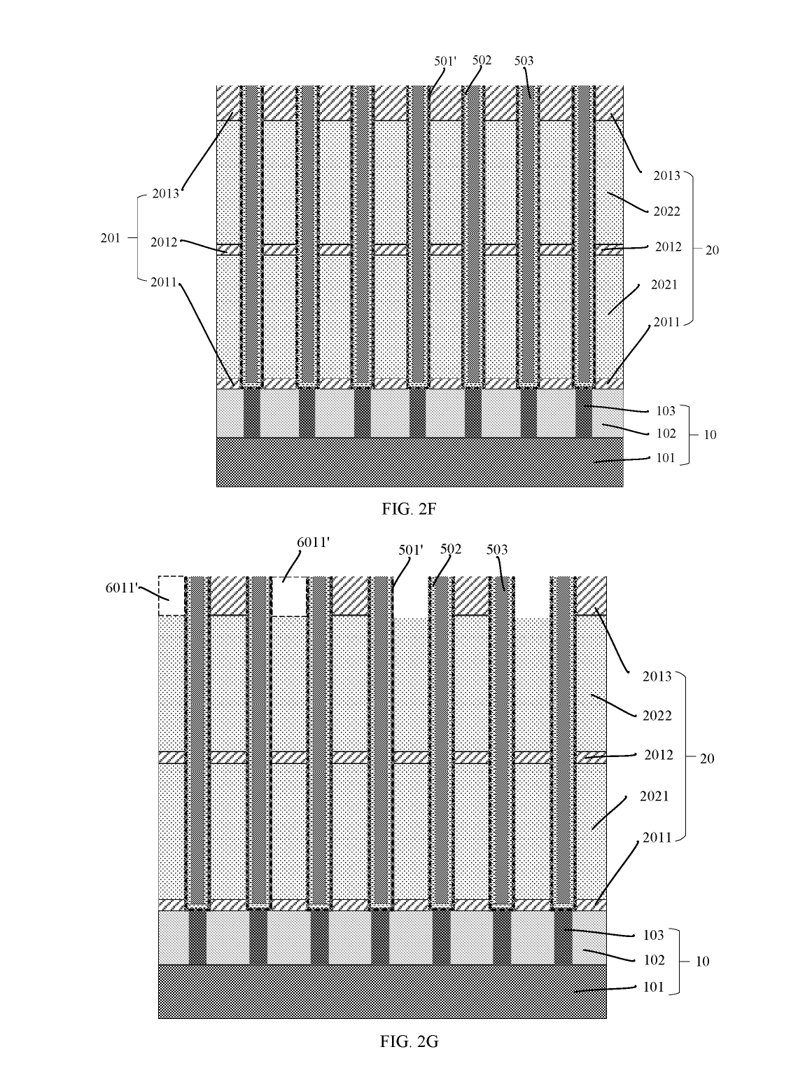

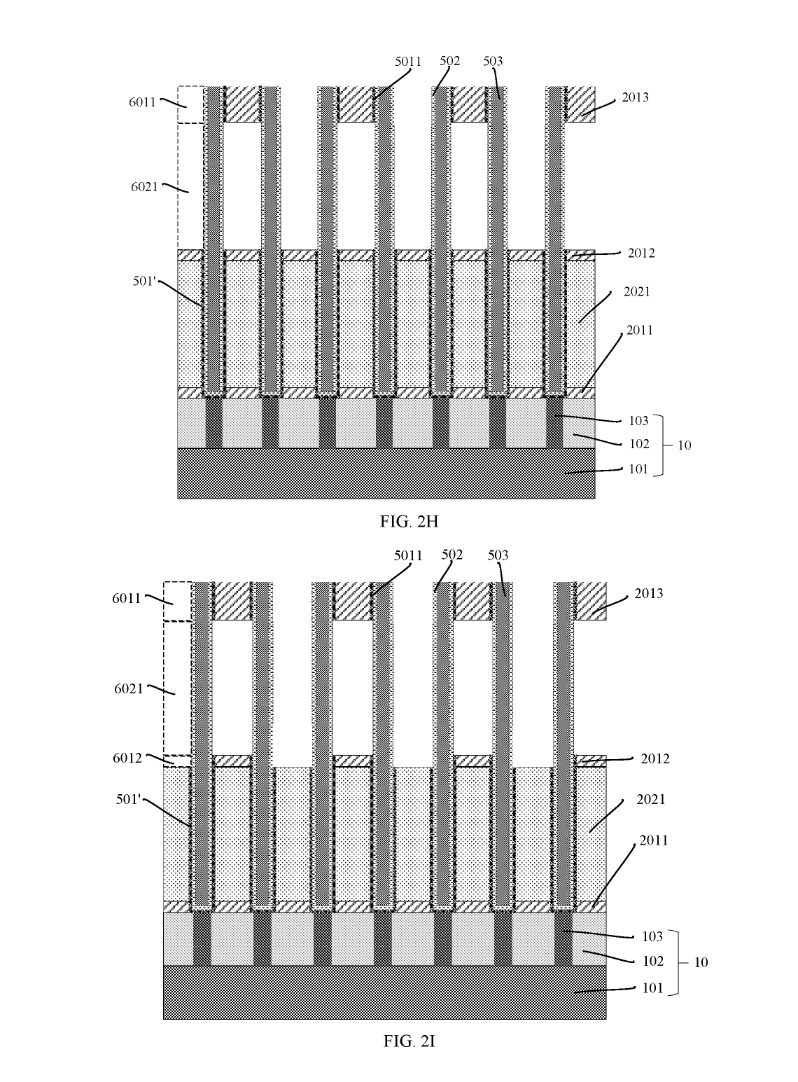

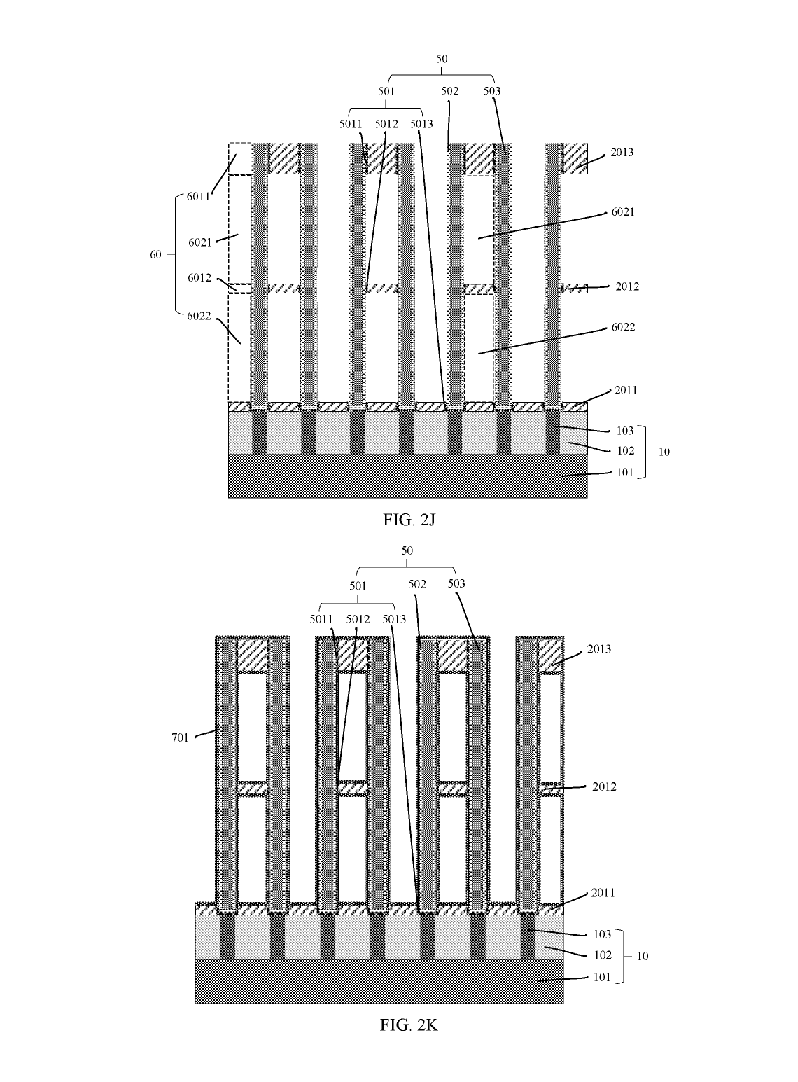

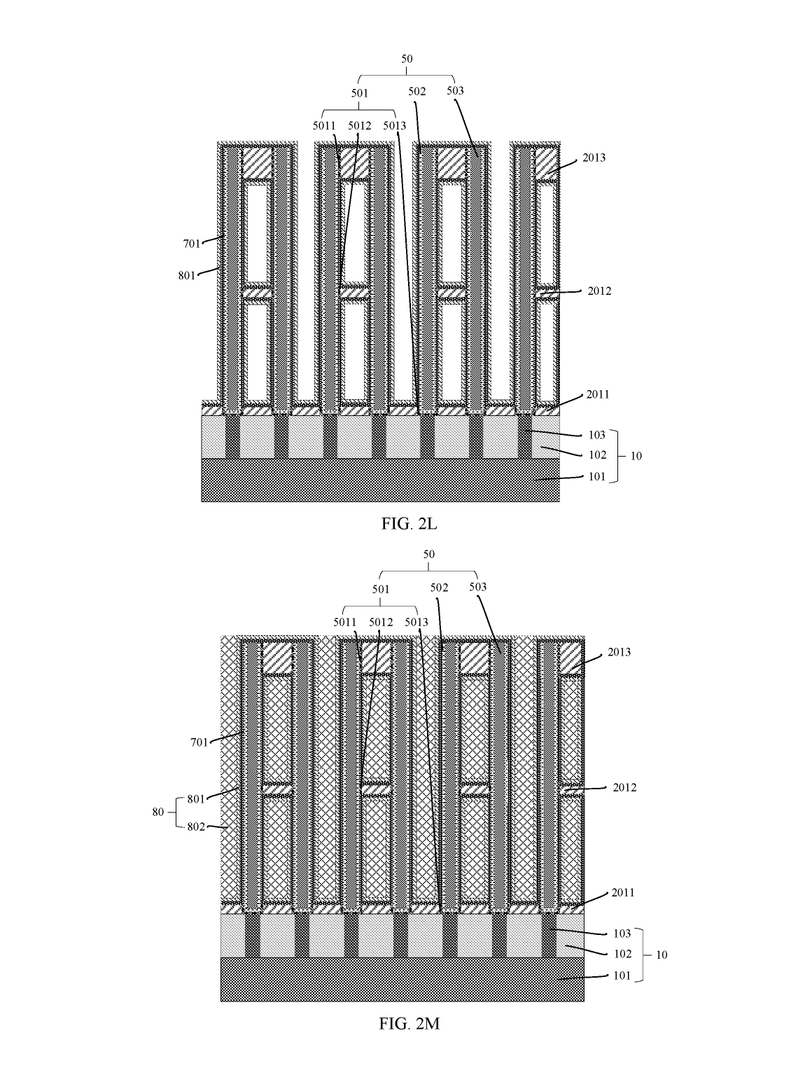

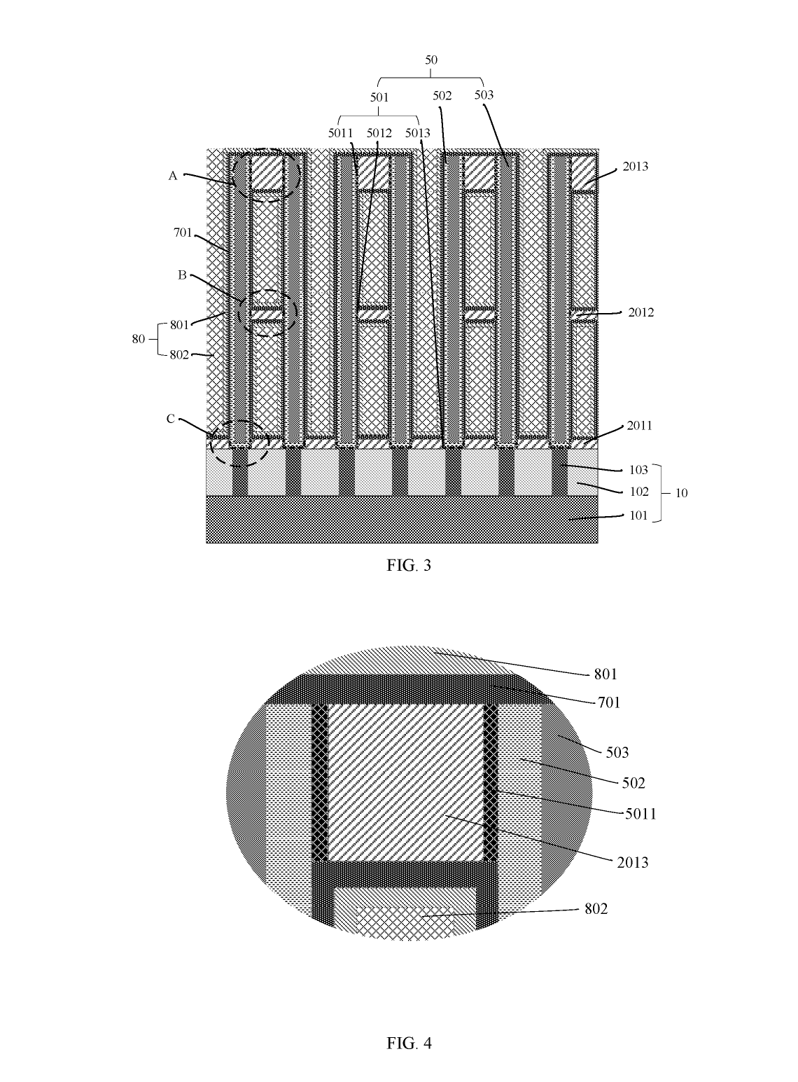

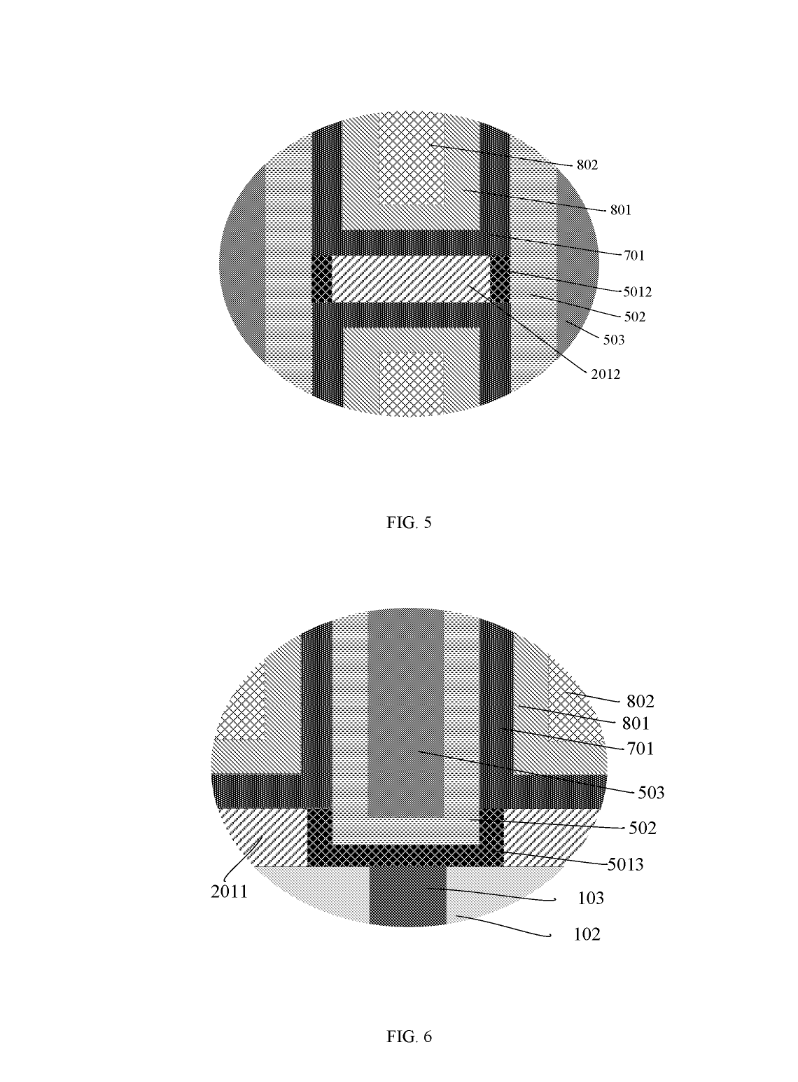

FIG. 1 is a flow block diagram of a method for manufacturing a semiconductor structure. FIGS. 2A to 2M are process flowcharts showing a method for manufacturing a semiconductor structure according to an embodiment of the present disclosure, where FIG. 2A is a schematic diagram showing the formation of a stack structure, FIG. 2B is a schematic diagram showing the formation of a first capacitor hole, FIG. 2C is a schematic diagram showing the formation of a first initial electrode layer, FIG. 2D is a schematic diagram showing the formation of a second electrode layer, FIG. 2E is a schematic diagram showing the formation of a third electrode layer, FIG. 2F is a schematic diagram showing the removal of a first initial electrode layer, a second electrode layer, and a third electrode layer that are above a top supporting layer, FIG. 2G is a schematic diagram showing the formation of an initial top opening, FIG. 2H is a schematic diagram showing the formation of a top opening and a first sacrificial opening, FIG. 2I is a schematic diagram showing the formation of an intermediate opening, FIG. 2J is a schematic diagram showing the formation of a second capacitor hole, FIG. 2K is a schematic diagram showing the formation of a dielectric layer, FIG. 2L is a schematic diagram showing the formation of a first upper electrode layer, and FIG. 2M is a schematic diagram showing the formation of a second upper electrode layer. FIG. 3 is a schematic diagram of a semiconductor structure according to an embodiment of the present disclosure, FIG. 4 is an enlarged schematic diagram of portion A in FIG. 3, FIG. 5 is an enlarged schematic diagram of portion B in FIG. 3, and FIG. 6 is an enlarged schematic diagram of portion C in FIG. 3.

As shown in FIG. 1, the manufacturing method at least includes the following steps: In S10, a base substrate is provided, and a stack structure is formed on the base substrate. In S20, the stack structure is etched to form a first capacitor hole. In S30, a first initial electrode layer, a second electrode layer, and a third electrode layer are sequentially formed in the first capacitor hole, where the oxidation resistance of the second electrode layer is greater than the oxidation resistances of the first initial electrode layer and the third electrode layer. In S40, a part of the stack structure and a part of the first initial electrode layer are removed to form a second capacitor hole, where a remaining part of the first initial electrode layer serves as a first electrode layer, and the first electrode layer, the second electrode layer, and the third electrode layer form a lower electrode. In S50, a dielectric layer and an upper electrode are formed in the second capacitor hole, where the dielectric layer covers the lower electrode, and the second capacitor hole is filled with the upper electrode.

The method for forming a semiconductor structure provided in the present application will be described in detail below with reference to the drawings.

Referring to FIGS. 1 and 2A, a base substrate 10 is provided, and a stack structure 20 is formed on the base substrate 10. The base substrate 10 includes a substrate 101 and an isolation layer 102 located on the substrate 101, and landing pads 103 spaced apart from each other are provided in the isolation layer 102. The stack structure 20 includes, from bottom to top, at least: a bottom supporting layer 2011, a first sacrificial layer 2021, an intermediate supporting layer 2012, a second sacrificial layer 2022, and a top supporting layer 2013. The intermediate supporting layer 2012 is located between the first sacrificial layer 2021 and the second sacrificial layer 2022, and the bottom supporting layer 2011, the intermediate supporting layer 2012, and the top supporting layer 2013 jointly form a supporting layer 201. Specifically, the material of the substrate 101 may be silicon (Si), germanium (Ge), silicon-germanium (GeSi), or silicon carbide (SiC), or may be silicon-on-insulator (SOI) or germanium-on-insulator (GOI), or may also be another material, for example, a group III-V compound, for example, gallium arsenide. The material of the substrate 101 in this embodiment is silicon. The material of the isolation layer 102 may be one or more of silicon dioxide, titanium dioxide, zirconium dioxide, hafnium dioxide, tantalum oxide, magnesium oxide, aluminum oxide, niobium oxide, molybdenum oxide, strontium oxide, barium oxide, yttrium oxide, a nitride material (for example, silicon nitride (Si3N4)), or an oxynitride (for example, silicon oxynitride). The material of the landing pad 103 may be a metal (for example, tungsten, titanium, nickel, platinum, rhodium, ruthenium, aluminum, copper, molybdenum, iridium, silver, or gold), a metal alloy, a metal-containing material (for example, a metal nitride, a metal silicide, a metal carbide, or a metal oxide), or the like. In this embodiment, the landing pad 103 may be made of tungsten, and a capacitor structure is electrically connected to a transistor in the base substrate by means of the landing pad. The material of the supporting layer 201 may be one or more of a nitride material (for example, silicon nitride (Si3N4)), an oxynitride (for example, silicon oxynitride), a carbon nitride material (for example, silicon nitride carbon (SiCN)), or an oxycarbonitride material (for example, silicon oxycarbonitride (SiOCN)). The materials of the first sacrificial layer 2021 and the second sacrificial layer 2022 may be one or more of phosphosilicate glass, borosilicate glass, borophosphosilicate glass (BPSG), or fluorosilicate glass. It should be noted that doping concentrations of the first sacrificial layer 2021 and the second sacrificial layer 2022 may be different. For example, both the first sacrificial layer 2021 and the second sacrificial layer 2022 are made of borophosphosilicate glass (BPSG), but the doping concentration of boron and phosphorus in the first sacrificial layer 2021 may be greater than the doping concentration of boron and phosphorus in the second sacrificial layer 2022. This is because the position of the first sacrificial layer 2021 is lower, and when the first sacrificial layer 2021 is removed subsequently, a higher doping concentration of the first sacrificial layer 2021 makes it easier to remove the first sacrificial layer, thereby simplifying the manufacturing process.

Referring to FIGS. 1 and 2B, the stack structure 20 is etched to form a first capacitor hole 401, and the first capacitor hole 401 may be formed by dry etching.

Referring to FIG. 1 and FIGS. 2C to 2E, a first initial electrode layer 501’, a second electrode layer 502, and a third electrode layer 503 are sequentially formed in the first capacitor hole 401. The first initial electrode layer 501' covers the side walls and the bottom of the first capacitor hole 401, the second electrode layer 502 covers the first initial electrode layer 501', and the remaining part of the first capacitor hole 401 is filled with the third electrode layer 503. The oxidation resistance of the second electrode layer 502 is greater than the oxidation resistances of the first initial electrode layer 501' and the third electrode layer 503.

Then, as shown in FIG. 2F, the first initial electrode layer 501', the second electrode layer 502, and the third electrode layer 503 that are above the top supporting layer 2013 are removed, such that the top surface of the top supporting layer 2013 is exposed.

Referring to FIG. 1 and FIGS. 2G to 2J, a part of the stack structure 20 and a part of the first initial electrode layer 501' are removed to form a second capacitor hole 60. A remaining part of the first initial electrode layer 501' serves as a first electrode layer 501; the first electrode layer 501, the second electrode layer 502, and the third electrode layer 503 form a lower electrode 50.

Specifically, as shown in FIG. 2G, a part of the top supporting layer 2013 is removed to form initial top openings 6011’, and the initial top openings 6011’ expose the side surface of a part of the first initial electrode layer 501' and the top surface of a part of the second sacrificial layer 2022. Specifically, as shown in FIG. 2G, in a direction parallel to the base substrate 10, the initial top openings 6011' may be spaced apart from each other; that is, the top supporting layer 2013 is provided between every two initial top openings 6011'.

Then, as shown in FIG. 2H, the exposed first initial electrode layer 501' is removed through the initial top openings 6011' to form top openings 6011, and the second sacrificial layer 2022 and the first initial electrode layer 501' corresponding to the second sacrificial layer 2022 are removed through the top openings 6011 to form first sacrificial openings 6021. That is, as shown in FIG. 2H, the second sacrificial layer 2022 and the first initial electrode layer 501' corresponding to the second sacrificial layer 2022 are completely removed. Specifically, the first initial electrode layer 501' may be removed with a mixture of ammonia, hydrogen peroxide, and water.

Then, as shown in FIG. 2I, a part of the intermediate supporting layer 2012 and the first initial electrode layer 501' corresponding to the intermediate supporting layer 2012 are continuously removed through the first sacrificial openings 6021 to form intermediate openings 6012. The projection of the intermediate opening 6012 on the base substrate 10 overlaps with the projection of the top opening 6011 on the base substrate 10, and the intermediate openings 6012 are spaced apart from each other; that is, the intermediate supporting layer 2012 is provided between every two intermediate openings 6012.

Then, as shown in FIG. 2J, the first sacrificial layer 2021 and the first initial electrode layer 501' corresponding to the first sacrificial layer 2021 are continuously etched and removed to form second sacrificial openings 6022. The remaining part of the first initial electrode layer 501' serves as the first electrode layer 501, and the first electrode layer 501 is at least located between the supporting layer 201 and the second electrode layer 502. That is, as shown in FIG. 2J, the first sacrificial layer 2021 and the first initial electrode layer 501' corresponding to the first sacrificial layer 2021 are completely removed; the top opening 6011, the first sacrificial opening 6021, the intermediate opening 6012, and the second sacrificial opening 6022 jointly form the second capacitor hole 60. Further, as shown in FIG. 2J, the first electrode layer 501 includes a top first electrode layer 5011, an intermediate first electrode layer 5012, and a bottom first electrode layer 5013; the top first electrode layer 5011 corresponds to the top supporting layer 2013, and the top first electrode layer 5011 is located only between the top supporting layer 2013 and the second electrode layer 502; the intermediate first electrode layer 5012 corresponds to the intermediate supporting layer 2012, and the intermediate first electrode layer 5012 is located only between the intermediate supporting layer 2012 and the second electrode layer 502; and the bottom first electrode layer 5013 corresponds to the bottom supporting layer 2011, and the bottom first electrode layer 5013 is located between the bottom supporting layer 2011 and the second electrode layer 502 and is located at the bottom of the first capacitor hole 401. The top supporting layer 2013, the intermediate supporting layer 2012, and the bottom supporting layer 2011 are provided between adjacent second capacitor holes 60, and the remaining part of the bottom supporting layer 2011, the intermediate supporting layer 2012, and the top supporting layer 2013, as well as the first electrode layer 501, the second electrode layer 502, and the third electrode layer 503 jointly provide a supporting force for the capacitor.

The first electrode layer 501, the second electrode layer 502, and the third electrode layer 503 jointly form the lower electrode 50, the landing pad 103 is electrically connected to the lower electrode 50, the first electrode layer 501 and the third electrode layer 503 may be made of titanium nitride, and the second electrode layer 502 may be made of titanium silicon nitride. The oxidation resistance of the second electrode layer 502 is greater than the oxidation resistances of the first electrode layer 501 and the third electrode layer 503; the resistivities of the first electrode layer 501 and the third electrode layer 503 are less than the resistivity of the second electrode layer 502; and the elastic modulus of the second electrode layer 502 is greater than the elastic moduli of the first electrode layer 501 and the third electrode layer 503. In the embodiments of the present application, the first initial electrode layer 501', the second electrode layer 502, and the third electrode layer 503 are sequentially formed in the first capacitor hole 401 first, and a part of the first initial electrode layer 501' is removed to form the first electrode layer 501. Since a part of the first initial electrode layer 501' is removed to form the first electrode layer 501, the radius of the lower electrode 50 of the capacitor is reduced, thereby further enabling the dimension of the semiconductor structure to be miniaturized. It should be noted that since a part of the first initial electrode layer 501' is removed, the radius of the lower electrode 50 in the part where the first initial electrode layer 501' is removed is reduced; that is, the radius of the lower electrode 50 varies across different cross sections of the capacitor structure. The part of the first initial electrode layer 501' corresponding to the supporting layer 201 is not removed, so the radius of the lower electrode 50 remains unchanged. However, the part of the first initial electrode layer 501' not corresponding to the supporting layer 201 is removed, such that the radius of the lower electrode 50 is reduced, enabling the dimension of the capacitor to be miniaturized. Moreover, the space left by the removal of the first initial electrode layer 501' provides more reserved space for subsequent deposition of the dielectric layer 701. In addition, alleviating the problem of capacitor bending and toppling is a critical aspect to improve the performance and reliability of the capacitor in an integrated circuit (IC). Capacitor toppling generally occurs in structures with a high aspect ratio, especially in deep-submicron technology nodes. When the dimension of the capacitor decreases and the height increases, the stability of the structure is affected, resulting in the inclination or collapse of the capacitor, thereby affecting the performance of the capacitor and the yield of the integrated circuit. In the embodiments of the present application, the first electrode layer 501, the second electrode layer 502, and the third electrode layer 503 with a different elastic modulus are provided. Specifically, the elastic modulus of the second electrode layer 502 is greater than the elastic moduli of the first electrode layer 501 and the third electrode layer 503. In a specific embodiment, the first electrode layer 501 and the third electrode layer 503 may be made of titanium nitride (TiN), the second electrode layer 502 may be made of titanium silicon nitride (TSN), and the elastic moduli of TIN and TiSiN are 220.433 GPa and 329.03 GPa, respectively. That is, the second electrode layer 502 exhibits a relatively high elastic modulus, which means that the second electrode layer can resist deformation and maintain the stability of the structure, such that the lower electrode 50 can maintain the verticality of the capacitor even under a high stress condition. The use of the lower electrode 50 with a high elastic modulus is beneficial to enhancing the mechanical strength of the capacitor and reducing the risk of toppling during the process of deposition, etching, or subsequent processing.

Referring to FIG. 1 and FIGS. 2K to 2M, a dielectric layer 701 and an upper electrode 80 are formed in the second capacitor hole 60; the dielectric layer 701 covers the lower electrode 50, and the second capacitor hole 60 is filled with the upper electrode 80.

Specifically, as shown in FIG. 2K, the dielectric layer 701 is formed in the second capacitor hole 60, the dielectric layer 701 covers the side walls and the bottom of the second capacitor hole and covers the inner walls of the first sacrificial opening 6021 and the second sacrificial opening 6022 between adjacent second capacitor holes 60, and the dielectric layer 701 further covers the tops of the top supporting layer 2013, the top first electrode layer 5011, the second electrode layer 502, and the third electrode layer 503. In a specific embodiment, the dielectric layer 701 may be made of one or more of zirconium oxide, hafnium oxide, tantalum oxide, or other high-k materials. The first electrode layer 501 and the third electrode layer 503 may be made of titanium nitride (TiN), and the second electrode layer 502 may be made of titanium silicon nitride (TiSiN, also abbreviated as TSN). During the formation of the dielectric layer 701, a hafnium precursor, a zirconium precursor, or a tantalum precursor needs to be oxidized by ozone to form hafnium oxide, zirconium oxide, or tantalum oxide. When the dielectric layer 701 is formed, TiN is more likely to be oxidized to TiON, whereas TSN is less likely to be oxidized, such that TSN exhibits stronger oxidation resistance. In addition, a high-k material may generate internal stress during a deposition process, particularly in a process such as atomic layer deposition (ALD) or chemical vapor deposition (CVD). The stress may be generated due to the mismatch between the coefficient of thermal expansion of the dielectric layer 701 and the coefficient of thermal expansion of a material of the lower electrode 50 (such as TiN or TSN), or due to chemical reactions during the deposition process. The accumulation of stress may cause bending or warping of the lower electrode 50. Since the oxidation resistance of the second electrode layer 502 is greater than the oxidation resistances of the first electrode layer 501 and the third electrode layer 503, when the dielectric layer 701 is deposited, deformation and bending caused by oxidation of the lower electrode 50 can be prevented, thereby improving the performance of the semiconductor structure. Specifically, applying a TSN (TiSiN) material having stronger oxidation resistance to the lower electrode 50 can reduce the deformation of the lower electrode 50 during the deposition of the dielectric layer 701, while also reducing the deformation of the TSN material during the thinning process of the lower electrode, ultimately preventing the lower electrode 50 of the capacitor from toppling over.

Then, as shown in FIGS. 2L to 2M, a first upper electrode layer 801 is formed on the dielectric layer 701 first, the first upper electrode layer 801 covers the dielectric layer 701, and then a second upper electrode layer 802 is formed. The remaining part of the second capacitor hole 60 is filled with the second upper electrode layer 802. The first upper electrode layer 801 and the second upper electrode layer 802 jointly form the upper electrode 80. Specifically, the first upper electrode layer 801 may be made of titanium nitride, and the second upper electrode layer 802 may be made of polycrystalline silicon. The first electrode layer 501, the second electrode layer 502, and the third electrode layer 503 jointly form the lower electrode 50, and the resistivities of the first electrode layer 501 and the third electrode layer 503 are less than the resistivity of the second electrode layer 502. In the embodiments of the present application, by removing a part of the first initial electrode layer 501' to form the first electrode layer 501, the radius of the lower electrode 50 of the capacitor is reduced, thereby further enabling the dimension of the semiconductor structure to be miniaturized. In addition, the elastic modulus of the second electrode layer 502 is greater than the elastic moduli of the first electrode layer 501 and the third electrode layer 503, and the oxidation resistance of the second electrode layer 502 is greater than the oxidation resistances of the first electrode layer 501 and the third electrode layer 503, such that the stability of the capacitor is maintained during the processes of etching and deposition. Here, the resistivities of the first electrode layer 501 and the third electrode layer 503 are less than the resistivity of the second electrode layer 502, such that the resistivity of the capacitor can be prevented from increasing while the capacitor structure remains stable. As shown in FIG. 2J, the first capacitor hole 401 is filled with the third electrode layer 503; that is, the thickness of the third electrode layer 503 in the direction parallel to the base substrate 10 is much greater than the thickness of the second electrode layer 502 in the direction parallel to the base substrate 10. In a specific embodiment, the first electrode layer 501 and the third electrode layer 503 may be made of titanium nitride (TiN), and the second electrode layer 502 may be made of titanium silicon nitride (TSN); the resistivity of titanium nitride (TIN) is generally 50 μΩ·cm (micro ohm·centimeter) to 150 μΩ·cm, and the resistivity of titanium silicon nitride (TiSiN) is generally 100 μΩ·cm to 300 μΩ·cm. The resistivities of the first electrode layer 501 and the third electrode layer 503 are less than the resistivity of the second electrode layer 502, and the thickness of the third electrode layer 503 in the direction parallel to the base substrate 10 is much greater than the thickness of the second electrode layer 502 in the direction parallel to the base substrate 10, such that the resistivity of the entire lower electrode 50 is reduced, thereby improving the performance of the capacitor structure.

In the present application, the first initial electrode layer 501' serves as a sacrificial layer, and a part of the first initial electrode layer 501' is removed to form the first electrode layer 501, such that the radius of the lower electrode 50 of the capacitor is reduced, thereby further enabling the dimension of the semiconductor structure to be miniaturized. In addition, the oxidation resistance of the second electrode layer 502 is greater than the oxidation resistances of the first electrode layer 501 and the third electrode layer 503, and the elastic modulus of the second electrode layer 502 is greater than the elastic moduli of the first electrode layer 501 and the third electrode layer 503, such that the stability of the capacitor structure is maintained during the processes of etching and deposition, preventing the capacitor form toppling over. Moreover, the resistivities of the first electrode layer 501 and the third electrode layer 503 are less than the resistivity of the second electrode layer 502, such that the resistivity of the entire lower electrode 50 is reduced. The configuration of each film layer of the lower electrode 50 described above can not only reduce the radius of the capacitor, enabling the semiconductor device to be miniaturized, but also prevent the phenomenon of capacitor bending and toppling and improve the performance of the capacitor structure.

FIG. 3 is a schematic diagram of a semiconductor structure according to an embodiment of the present disclosure; FIG. 4 is an enlarged schematic diagram of portion A in FIG. 3; FIG. 5 is an enlarged schematic diagram of portion B in FIG. 3; and FIG. 6 is an enlarged schematic diagram of portion C in FIG. 3. The following is a detailed description of each figure.

Specifically, referring to FIGS. 2B, 2J, and 3, provided is a semiconductor structure. The semiconductor structure includes: a base substrate 10, where a stack structure 20 is provided on the base substrate 10, and the stack structure 20 is provided with first capacitor holes 401; a lower electrode 50, located in the first capacitor hole 401, where the lower electrode 50 at least includes a first electrode layer 501, a second electrode layer 502, and a third electrode layer 503, the oxidation resistance of the second electrode layer 502 being greater than the oxidation resistances of the first electrode layer 501 and the third electrode layer 503; a second capacitor hole 60, formed by removing at least a part of the stack structure 20; and a dielectric layer 701 and an upper electrode 80, located in the second capacitor hole 60, where the dielectric layer 701 covers the lower electrode 50, and the second capacitor hole 60 is filled with the upper electrode 80. The base substrate 10 includes a substrate 101 and an isolation layer 102 located on the substrate 101, and landing pads 103 spaced apart from each other are provided in the isolation layer 102. The resistivities of the first electrode layer 501 and the third electrode layer 503 are less than the resistivity of the second electrode layer 502, and the elastic modulus of the second electrode layer 502 is greater than the elastic moduli of the first electrode layer 501 and the third electrode layer 503. The stack structure 20 includes, from bottom to top, at least: a bottom supporting layer 2011, a first sacrificial layer 2021, an intermediate supporting layer 2012, a second sacrificial layer 2022, and a top supporting layer 2013. The intermediate supporting layer 2012 is located between the first sacrificial layer 2021 and the second sacrificial layer 2022, and the bottom supporting layer 2011, the intermediate supporting layer 2012, and the top supporting layer 2013 jointly form a supporting layer 201. The first electrode layer 501 is at least located between the supporting layer 201 and the second electrode layer 502; the first electrode layer 501 includes a top first electrode layer 5011, an intermediate first electrode layer 5012, and a bottom first electrode layer 5013; the top first electrode layer 5011 corresponds to the top supporting layer 2013, and the top first electrode layer 5011 is located only between the top supporting layer 2013 and the second electrode layer 502; the intermediate first electrode layer 5012 corresponds to the intermediate supporting layer 2012, and the intermediate first electrode layer 5012 is located only between the intermediate supporting layer 2012 and the second electrode layer 502; and the bottom first electrode layer 5013 corresponds to the bottom supporting layer 2011, and the bottom first electrode layer 5013 is located between the bottom supporting layer 2011 and the second electrode layer 502 and is located at the bottom of the first capacitor hole 401. The first electrode layer 501 and the third electrode layer 503 may be made of titanium nitride, and the second electrode layer 502 may be made of titanium silicon nitride; the resistivity of titanium nitride (TIN) is generally 50 μΩ·cm (micro ohm·centimeter) to 150 μΩ·cm, and the resistivity of titanium silicon nitride (TiSiN) is generally 100 μΩ·cm to 300 μΩ·cm. The elastic moduli of TIN and TiSiN are 220.433 GPa and 329.03 GPa, respectively. During the formation of the dielectric layer 701, a hafnium precursor, a zirconium precursor, or a tantalum precursor needs to be oxidized by ozone to form hafnium oxide, zirconium oxide, or tantalum oxide. When the dielectric layer 701 is formed, TiN is more likely to be oxidized to TiON, whereas TSN is less likely to be oxidized, such that TiSiN exhibits stronger oxidation resistance.

In the present application, the first initial electrode layer 501' serves as a sacrificial layer, and a part of the first initial electrode layer 501' is removed to form the first electrode layer 501, such that the radius of the lower electrode 50 of the capacitor is reduced, thereby further enabling the dimension of the semiconductor structure to be miniaturized. In addition, the oxidation resistance of the second electrode layer 502 is greater than the oxidation resistances of the first electrode layer 501 and the third electrode layer 503, and the elastic modulus of the second electrode layer 502 is greater than the elastic moduli of the first electrode layer 501 and the third electrode layer 503, such that the stability of the capacitor structure is maintained during the processes of etching and deposition, preventing the capacitor form toppling over. Moreover, the resistivities of the first electrode layer 501 and the third electrode layer 503 are less than the resistivity of the second electrode layer 502, such that the resistivity of the entire lower electrode 50 is reduced. The configuration of each film layer of the lower electrode 50 described above can not only reduce the radius of the capacitor, enabling the semiconductor device to be miniaturized, but also prevent the phenomenon of capacitor bending and toppling and improve the performance of the capacitor structure.

FIG. 4 is an enlarged schematic diagram of portion A in FIG. 3. As can be seen from FIG. 4, the top first electrode layer 5011 is located on two sides of the top supporting layer 2013, the thickness of the second electrode layer 502 in the direction parallel to the base substrate 10 is greater than the thickness of the top first electrode layer 5011 in the direction parallel to the base substrate 10, and both the upper surface and the lower surface of the top supporting layer 2013 are covered by the dielectric layer 701. FIG. 5 is an enlarged schematic diagram of portion B in FIG. 3. As can be seen from FIG. 5, the intermediate first electrode layer 5012 is located on two sides of the intermediate supporting layer 2012, the thickness of the second electrode layer 502 in the direction parallel to the base substrate 10 is greater than the thickness of the intermediate first electrode layer 5012 in the direction parallel to the base substrate 10, and both the upper surface and the lower surface of the intermediate supporting layer 2012 are covered by the dielectric layer 701. FIG. 6 is an enlarged schematic diagram of portion C in FIG. 3. As can be seen from FIG. 6, the bottom first electrode layer 5013 is located on two sides of the bottom supporting layer 2011, and the bottom first electrode layer 5013 is further located at the bottom of the first capacitor hole 401. The thickness of the second electrode layer 502 in the direction parallel to the base substrate 10 is greater than the thickness of the bottom first electrode layer 5013 in the direction parallel to the base substrate 10. The bottom first electrode layer 5013 is electrically connected to the landing pad 103, and the orthographic projection of the landing pad 103 on the base substrate 10 is located within the orthographic projection of the bottom first electrode layer 5013 on the base substrate 10. The bottom first electrode layer 5013 is in a groove shape and provided with a bottom and side walls. The second electrode layer 502 covers the bottom of the bottom first electrode layer 5013, and the dielectric layer 701 covers the top surfaces of the side walls of the bottom first electrode layer 5013. In the present application, the thickness of the second electrode layer 502 in the direction parallel to the base substrate 10 is greater than the thickness of the first electrode layer 501 in the direction parallel to the base substrate 10. In addition, since the oxidation resistance of the second electrode layer 502 is greater than the oxidation resistances of the first electrode layer 501 and the third electrode layer 503, and the elastic modulus of the second electrode layer 502 is greater than the elastic moduli of the first electrode layer 501 and the third electrode layer 503, the capacitor structure achieves stronger stability, preventing the toppling or short circuit of the capacitor structure.

In the capacitor structure, compared with the lower electrode including only one layer, the lower electrode including the first electrode layer 501, the second electrode layer 502, and the third electrode layer 503 according to this solution achieves superior performance in all aspects. In a specific embodiment, a lower electrode of an X capacitor includes a composite layer made of TiN, TiSiN, and TiN, and a lower electrode of a Y capacitor includes only one TiN layer. The critical dimension (critical dimension, CD) of the X capacitor is the same as the critical dimension of the Y capacitor, the porosity of the X capacitor is 0.02% to 0.06%, the porosity of the Y capacitor is 5% to 7%, the bending rate of the X capacitor is 0%, and the bending rate of the Y capacitor is 10% to 14%. It should be noted that the porosity here refers to the ratio of the number of capacitors containing voids to the total number of capacitors. The cause of void formation in the capacitors is roughly as follows: When the lower electrode plate is only made of TiN, TiN, when deposited to a certain thickness, crystallizes to form a relatively large crystalline grain, and the presence of the relatively large crystalline grain causes the top of the capacitor hole to be sealed first, forming voids. However, in the present application, the lower electrode is configured to include at least three film layers: the first electrode layer 501, the second electrode layer 502, and the third electrode layer 503. That is, the original thickness of one layer made of TiN is D1, and now the sum of thicknesses of the three layers is D1, which is equivalent to the reduction of the thickness of TiN, such that TiN cannot meet the condition for forming a large crystalline grain. Moreover, in the present application, the first electrode layer 501 and the third electrode layer 503 are made of titanium nitride (TiN), the second electrode layer 502 is made of titanium silicon nitride (TiSiN), and the thickness of the second electrode layer TiSiN is much greater than the thickness of the first electrode layer, such that the capacitor hole using the technical solutions of the present application is less likely to be sealed to form voids, resulting in a lower porosity. The low porosity enables the capacitor to achieve better electrical performance and stability. In addition, the bending rate of the capacitor refers to the ratio of the number of bent capacitors to the total number of capacitors. A capacitor X manufactured by using the technical solutions of the present application has a bending rate of 0, while a capacitor Y, whose lower electrode includes only one TiN layer, has a bending rate of 10% to 14%. Capacitor bending causes capacitors that are originally independent of each other to topple over and be connected together, such that the capacitor is short-circuited, forming a fail bit. This seriously affects the performance of the capacitor. Therefore, adopting the solutions of the present application can improve the stability of the capacitor, prevent the capacitor from bending, and improve the performance of the capacitor.

Those of ordinary skill in the art can understand that the foregoing implementations are specific embodiments of practicing the present disclosure, while in practical application, various changes can be made to the implementations in form and detail without departing from the spirit and scope of the present disclosure. Any person skilled in the art can make various changes and modifications without departing from the spirit and scope of the present disclosure, and the protection scope of the present disclosure shall be defined by the appended claims.

What is claimed is:

1. A method for manufacturing a semiconductor structure, comprising:
providing a base substrate, and forming a stack structure on the base substrate;
etching the stack structure to form a first capacitor hole;
forming a first initial electrode layer, a second electrode layer, and a third electrode layer sequentially in the first capacitor hole, wherein an oxidation resistance of the second electrode layer is greater than oxidation resistances of the first initial electrode layer and the third electrode layer;
removing a part of the stack structure and a part of the first initial electrode layer to form a second capacitor hole, with a remaining part of the first initial electrode layer serving as a first electrode layer, wherein the first electrode layer, the second electrode layer, and the third electrode layer form a lower electrode; and
forming a dielectric layer and an upper electrode in the second capacitor hole, wherein the dielectric layer covers the lower electrode, and the second capacitor hole is filled with the upper electrode.

2. The method for manufacturing a semiconductor structure according to claim 1, wherein resistivities of the first electrode layer and the third electrode layer are less than a resistivity of the second electrode layer; and an elastic modulus of the second electrode layer is greater than elastic moduli of the first electrode layer and the third electrode layer.

3. The method for manufacturing a semiconductor structure according to claim 1, wherein the first initial electrode layer covers the first capacitor hole, the second electrode layer covers the first initial electrode layer, and a remaining part of the first capacitor hole is filled with the third electrode layer.

4. The method for manufacturing a semiconductor structure according to claim 1, wherein an isolation layer is further provided in the base substrate, a landing pad is located in the isolation layer, and the landing pad is electrically connected to the lower electrode.

5. The method for manufacturing a semiconductor structure according to claim 1, wherein the first electrode layer and the third electrode layer are made of titanium nitride, and the second electrode layer is made of titanium silicon nitride.

6. The method for manufacturing a semiconductor structure according to claim 1, wherein the stack structure comprises, from bottom to top, at least: a bottom supporting layer, a first sacrificial layer, an intermediate supporting layer, a second sacrificial layer, and a top supporting layer; the intermediate supporting layer is located between the first sacrificial layer and the second sacrificial layer, and the bottom supporting layer, the intermediate supporting layer, and the top supporting layer jointly form a supporting layer.

7. The method for manufacturing a semiconductor structure according to claim 6, wherein removing the part of the stack structure and the part of the first initial electrode layer to form the second capacitor hole, with the remaining part of the first initial electrode layer serving as the first electrode layer at least comprises: removing a part of the top supporting layer to form an initial top opening, the initial top opening exposing a side surface of a part of the first initial electrode layer and a top surface of a part of the second sacrificial layer, and removing the exposed first initial electrode layer through the initial top opening to form a top opening; and removing at least the first sacrificial layer and the second sacrificial layer through the top opening, and removing the first initial electrode layer corresponding to the first sacrificial layer and the second sacrificial layer, with a remaining part of the first initial electrode layer serving as a first electrode layer, wherein the first electrode layer is at least located between the supporting layer and the second electrode layer.

8. The method for manufacturing a semiconductor structure according to claim 7, wherein the first electrode layer comprises a top first electrode layer, an intermediate first electrode layer, and a bottom first electrode layer; the top first electrode layer corresponds to the top supporting layer, and the top first electrode layer is located only between the top supporting layer and the second electrode layer; the intermediate first electrode layer corresponds to the intermediate supporting layer, and the intermediate first electrode layer is located only between the intermediate supporting layer and the second electrode layer; and the bottom first electrode layer corresponds to the bottom supporting layer, and the bottom first electrode layer is located between the bottom supporting layer and the second electrode layer and is located at a bottom of the first capacitor hole.

9. A semiconductor structure, comprising:
a base substrate, wherein a stack structure is provided on the base substrate, and the stack structure is provided with a first capacitor hole;
a lower electrode, located in the first capacitor hole, wherein the lower electrode at least comprises a first electrode layer, a second electrode layer, and a third electrode layer, an oxidation resistance of the second electrode layer being greater than oxidation resistances of the first electrode layer and the third electrode layer;
a second capacitor hole, formed by removing at least a part of the stack structure; and
a dielectric layer and an upper electrode, located in the second capacitor hole, wherein the dielectric layer covers the lower electrode, and the second capacitor hole is filled with the upper electrode.

10. The semiconductor structure according to claim 9, wherein resistivities of the first electrode layer and the third electrode layer are less than a resistivity of the second electrode layer; and an elastic modulus of the second electrode layer is greater than elastic moduli of the first electrode layer and the third electrode layer.

11. The semiconductor structure according to claim 9, wherein an isolation layer is provided in the base substrate, a landing pad is located in the isolation layer, and the landing pad is electrically connected to the lower electrode.

12. The semiconductor structure according to claim 9, wherein the first electrode layer and the third electrode layer are made of titanium nitride, and the second electrode layer is made of titanium silicon nitride.

13. The semiconductor structure according to claim 9, wherein the stack structure comprises, from bottom to top, at least: a bottom supporting layer, a first sacrificial layer, an intermediate supporting layer, a second sacrificial layer, and a top supporting layer; the intermediate supporting layer is located between the first sacrificial layer and the second sacrificial layer, and the bottom supporting layer, the intermediate supporting layer, and the top supporting layer jointly form a supporting layer.

14. The semiconductor structure according to claim 13, wherein the first electrode layer is at least located between the supporting layer and the second electrode layer.

15. The semiconductor structure according to claim 14, wherein the first electrode layer comprises a top first electrode layer, an intermediate first electrode layer, and a bottom first electrode layer; the top first electrode layer corresponds to the top supporting layer, and the top first electrode layer is located only between the top supporting layer and the second electrode layer; the intermediate first electrode layer corresponds to the intermediate supporting layer, and the intermediate first electrode layer is located only between the intermediate supporting layer and the second electrode layer; and the bottom first electrode layer corresponds to the bottom supporting layer, and the bottom first electrode layer is located between the bottom supporting layer and the second electrode layer and is located at a bottom of the first capacitor hole.
